(19) United States
(12) Patent Application Publication
(10) Pub. No.: US 2025/0287498 A1
(43) Pub. Date: Sep. 11, 2025

(54) PRINTED CIRCUIT BOARD

(71) Applicant: SAMSUNG ELECTRO-MECHANICS CO., LTD., Suwon-si (KR)

(72) Inventors: Kyung Ho LEE, Suwon-si (KR); Kyung Moon JUNG, Suwon-si (KR)

(73) Assignee: SAMSUNG ELECTRO-MECHANICS CO., LTD., Suwon-si (KR)

(21) Appl. No.: 19/052,706

(22) Filed: Feb. 13, 2025

(30) Foreign Application Priority Data
Mar. 8, 2024 (KR) 10-2024-0033073

(51) Int. Cl. H05K 1/03

(52) U.S. Cl. CPC H05K 1/0306; H05K 2201/068; H05K 2201/096; H05K 2201/2081

(57) ABSTRACT

A printed circuit board includes a glass layer, a first insulating layer disposed on the glass layer, a first interconnection layer disposed on the first insulating layer, and a first protective layer covering a portion of an upper surface of the glass layer, at least a portion of a side surface of the glass layer, and at least a portion of a side surface of the first insulating layer.

### CROSS-REFERENCE TO RELATED APPLICATION(S)

This application claims the benefit of priority to Korean Patent Application No. 10-2024-0033073 filed on Mar. 8, 2024 in the Korean Intellectual Property Office, the disclosure of which is incorporated herein by reference in its entirety.

### TECHNICAL FIELD

The present disclosure relates to a printed circuit board.

### BACKGROUND

Recently, due to the development of artificial intelligence (AI) technology, etc., multi-chip packages including memory chips, such as high bandwidth memory (HBM) for exponentially increased data processing and processor chips, such as central processing unit (CPU), graphics processing unit (GPU), application specific integrated circuit (ASIC), and field programmable gate array (FPGA) have been used. In particular, the number of CPU and GPU cores in server products has rapidly increased, and demand for large-area substrates has increased. Since glass materials have thermal/mechanical stability, warpage problems may be overcome in using glass materials, and thus, attempts to use glass materials has continued.

### SUMMARY

An aspect of the present disclosure is to provide a printed circuit board including a glass layer.

Another aspect of the present disclosure is to provide a printed circuit board that may complement the problem of the breakage characteristics of a glass layer.

Another aspect of the present disclosure is to provide a printed circuit board having improved reliability.

According to an aspect of the present disclosure, a printed circuit board includes: a glass layer; a first insulating layer disposed on the glass layer; a first interconnection layer disposed on the first insulating layer; and a first protective layer covering a portion of an upper surface of the glass layer, at least a portion of a side surface of the glass layer, and at least a portion of a side surface of the first insulating layer.

According to another aspect of the present disclosure, a printed circuit board includes: a glass layer; a first insulating layer disposed on the glass layer; and a first interconnection layer disposed on the first insulating layer, wherein a width of the first insulating layer is smaller than a width of the first glass layer.

### BRIEF DESCRIPTION OF DRAWINGS

The and other aspects, features, and advantages of the present disclosure will be more clearly understood from the following detailed description, taken in conjunction with the accompanying drawings, in which:

FIG. 1 is a cross-sectional view schematically illustrating an example of a printed circuit board;

FIG. 2 is a cross-sectional view schematically illustrating another example of a printed circuit board;

FIG. 3 is a cross-sectional view schematically illustrating another example of a printed circuit board;

FIG. 4 is a cross-sectional view schematically illustrating another example of a printed circuit board; and

FIGS. 5 to 8 are cross-sectional views schematically illustrating an example of a method for manufacturing a printed circuit board.

### DETAILED DESCRIPTION

Hereinafter, the present disclosure will be described with reference to the accompanying drawings. The shapes and sizes of elements in the drawings may be exaggerated or reduced for clarification.

### Printed Circuit Board

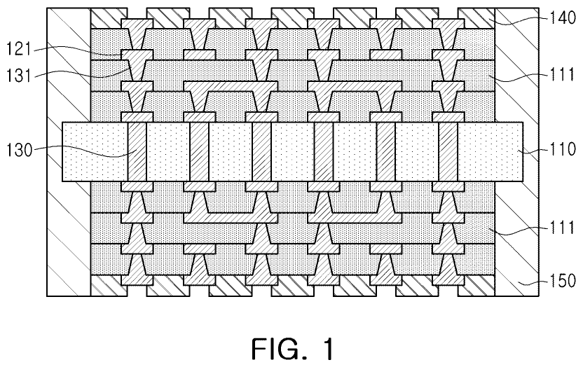

FIG. 1 is a cross-sectional view schematically illustrating an example of a printed circuit board.

Referring to FIG. 1, a printed circuit board (PCB) according to an example may include a glass layer 110, a first insulating layer 111 disposed on the glass layer 110, a first interconnection layer 121 disposed on the first insulating layer 111, and a first protective layer 150 covering a portion of an upper surface of the glass layer 110, at least a portion of a side surface of the glass layer 110, and at least a portion of a side surface of the first insulating layer 111. In addition, in the PCB according to an example, a coefficient of thermal expansion of the first protective layer 150 may be greater than that of the first insulating layer 111.

Since the PCB according to an example includes the glass layer 110, the PCB may have excellent flatness and may also be advantageous in controlling warpage through a low coefficient of thermal expansion (CTE), etc. In particular, since the PCB according to the example may have the glass layer 110 as a core, it is advantageous for warpage control of the completed PCB and may also be advantageous for warpage control in a stage of stacking other insulating layers. In addition, the flatness may be further increased, and therefore, it may be more advantageous for forming a high-density microcircuit with a fine pitch. In addition, the number of layers of the PCB may be reduced and the design freedom may be further increased through the characteristics of the glass having dielectric properties of the glass layer 110, for example, a variable property of Dk 2.5 to 11.

The glass layer 110 may include glass, which is an amorphous solid. The glass may include, for example, pure silicon dioxide (about 100% SiO₂), soda lime glass, borosilicate glass, alumino-silicate glass, etc. However, the present disclosure is not limited thereto, and alternative glass materials, such as fluorine glass, phosphate glass, chalcogen glass, etc., may also be used as the material of the glass layer 110. In addition, other additives may be further included to form glass having specific physical properties. These additives may include not only calcium carbonate (e.g., lime) and sodium carbonate (e. g., soda), but also magnesium, calcium, manganese, aluminum, lead, boron, iron, chromium, potassium, sulfur, and antimony, and carbonates and/or oxides of these elements and other elements. The glass layer 110 is a layer distinct from materials including glass fiber (glass cloth, glass fabric, etc.), such as copper clad laminate (CCL), prepreg (PPG), etc., and may be understood as, for example, plate glass.

The first insulating layer 111 may include one or more insulating layers and may include an organic insulating material. The organic insulating material may include a thermosetting resin, such as an epoxy resin, a thermoplastic resin, such as a polyimide, or a material including an inorganic filler, an organic filler, and/or glass fiber (glass cloth, glass fabric) together with the resin. For example, the insulating material may be a non-photosensitive insulating material, such as Ajinomoto build-up film (ABF) or PPG, but is not limited thereto, and other polymer materials may also be used. In addition, the insulating material may be a photosensitive insulating material, such as photo imageable dielectric (PID). In addition, the insulating material may include an adhesive sheet, such as bonding sheet (BS). The first insulating layer 111 may be disposed on each of upper and lower surfaces of the glass layer 110.

A width of the first insulating layer 111 may be narrower than a width of the glass layer 110. The PCB according to an example may be a result of performing an operation of forming the first insulating layer 111 on the glass layer 110, removing a portion of the first insulating layer 111, and then performing an operation of cutting the glass layer 110.

In order to increase the production yield, the PCB may be manufactured in a panel shape or strip unit, and then singulation may be performed to complete individual unit substrates. Here, when cutting the strip substrate for singulation, expansion or contraction may occur more in the first insulating layer 111 having a relatively greater coefficient of thermal expansion than in the glass layer 110 having a relatively smaller coefficient of thermal expansion. Here, when cooling is performed in the singulation operation, the first insulating layer 111 may contract more, causing a difference in stress with the glass layer 110, and a tensile stress may occur on the side of the glass layer 110, which may lead to cracks occurring on the side of the glass layer 110. A PCB with cracks may be defective, but microcracks occurring inside and outside the glass layer 110 may cause a defect during subsequent use of the PCB.

According to an example, since singulation is performed in an operation of cutting the glass layer 110 after an operation of removing a portion of the first insulating layer 111, the stress occurring when the first insulating layer 111 and the glass layer 110 are cut at the same time may be minimized, and here, a groove may be formed by removing more than a cutting position for singulation, thereby removing a portion of the first insulating layer 111. Therefore, since a portion of the first insulating layer 111 is removed further than the position in which the glass layer 110 is cut, the width of the first insulating layer 111 according to an example may be narrower than the width of the glass layer 110.

A width of the first insulating layer 111 may be measured by imaging a cross-section of the PCB cut in a stacking direction using a scanning microscope, etc. The width of the first insulating layer 111 may refer to a horizontal distance crossing between both sides of the first insulating layer 111 and may be an average value of distances measured at five arbitrary points. The width of the glass layer 110 may also be measured in the same sense and may be measured as a horizontal distance crossing between both sides of the glass layer 110.

The first interconnection layer 121 may include one or more interconnection layers and may include metal. The metal may include copper (Cu), aluminum (Al), silver (Ag), tin (Sn), gold (Au), nickel (Ni), lead (Pb), titanium (Ti), and/or alloys thereof. Preferably, the first interconnection layer 121 may include copper (Cu), but is not limited thereto. Each of the first interconnection layers 121 may perform various functions according to the design. For example, the first interconnection layers 121 may include a signal pattern, a power pattern, a ground pattern, etc. Each of these patterns may have various shapes, such as a line, a plane, a pad, etc. Each of the first interconnection layers 121 may include an electroless plating layer (or chemical copper) and an electrolytic plating layer (or electrolytic copper). Alternatively, each of the first interconnection layers 121 may include a metal foil (or copper foil) and an electrolytic plating layer (or electrolytic copper). Alternatively, each of the first interconnection layers 121 may include a metal foil (or copper foil), an electroless plating layer (or chemical copper), and an electrolytic plating layer (or electrolytic copper). Each of the first interconnection layers 121 may include a sputtering layer, instead of the electroless plating layer (or chemical copper) and may include both if necessary. The first interconnection layer 121 may be disposed on the first insulating layer 111, but is not limited thereto, and may also be disposed on an upper surface and/or lower surface of the glass layer 110.

The first interconnection layer 121 may be formed by any one of semi additive process (SAP), modified semi additive process (MSAP), tenting (TT), or a subtractive method, but is not limited thereto, and any method that may form a circuit on a PCB may be used without limitation. In addition, the first interconnection layer 121 may be formed by different methods depending on the purpose and design, etc.

The PCB according to an example may further include a first via layer 131 penetrating through at least a portion of the first insulating layer 111 to connect the first interconnection layers 121 to each other.

The first via layer 131 may include a metal. The metal may include copper (Cu), aluminum (Al), silver (Ag), tin (Sn), gold (Au), nickel (Ni), lead (Pb), titanium (Ti), and/or alloys thereof. Preferably, the first via layer 131 may include copper (Cu), but is not limited thereto. The first via layer 131 may include a filled via filling each via hole, but may also include a conformal via disposed along a wall surface of the via hole. The first via layer 131 may perform various functions depending on the design. For example, the first via layer 131 may include a ground via, a power via, a signal via, etc. The first via layer 131 may include an electroless plating layer (or chemical copper) and an electrolytic plating layer (or electrolytic copper), similar to the first interconnection layer 121. Alternatively, the first via layer 131 may include a metal foil (or copper foil) and an electrolytic plating layer (or electrolytic copper). The first via layer 131 may include a sputtering layer, instead of an electroless plating layer (or chemical copper) or may include both if necessary.

The PCB according to the example may further include a through-via 130 penetrating through the glass layer 110.

The through-via 130 may include a metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu), but is not limited thereto. The through-via 130 may penetrate through the upper and lower surfaces of the glass layer 110. Upper and lower surfaces of the through-via 130 may be substantially coplanar with the upper and lower surfaces of the glass layer 110, respectively. The through-via 130 may be filled with a single metal layer and may be a so-called a filled via. However, without being limited thereto, the through-via 130 may have various structures. For example, the through-via 130 may be a conformal via disposed along a wall surface of the via hole. The through-via 130 may perform various functions depending on the design. For example, the through-via 130 may include a ground via, a power via, a signal via, etc. The through-via 130 may have a roughly circular or elliptical shape, a polygonal shape on a plane, but is not limited thereto. For example, the through-via 130 may have a composite shape in which various shapes are combined into one on a plane in terms of securing close contact through increasing a specific surface area. A side surface of the through-via 130 may be substantially perpendicular to the upper and lower surfaces of the through-via 130, but is not limited thereto, and may be tapered to have an hourglass shape, etc. on a cross-section if necessary.

The PCB according to an example may further include a solder resist layer 140 disposed on the first insulating layer 111. The solder resist layer 140 may be disposed on the uppermost and lowermost sides of the PCB to protect the PCB from the outside. The solder resist layer 140 may use a known solder resist, and the solder resist layer 140 may include a liquid or film type material, but is not limited thereto, and other types of insulating materials may be used. The solder resist layer 140 may include a thermosetting resin and an inorganic filler dispersed in the thermosetting resin, but may not include glass fiber. The insulating resin may be a photosensitive insulating resin, and the filler may be an inorganic filler and/or an organic filler, but is not limited thereto, and other polymer materials may be used as needed. The solder resist layer 140 may have an opening, and at least a portion of the first interconnection layer 121 may be exposed through the opening. The first interconnection layer 121 exposed through the opening may be connected to a device, such as a semiconductor chip, and may also be connected to a main board or another PCB. The interconnection layer exposed through the opening functions as a pad, and a surface treatment layer may be further formed on the pad as needed. Alternatively, a metal bump or post may be further formed on the pad, or the pad may have a structure protruding in a pillar shape as needed.

The PCB according to an example may include a first protective layer 150 covering a portion of the upper surface of the glass layer 110, at least a portion of the side surface of the glass layer 110, and at least a portion of the side surface of the first insulating layer 111. That is, the first protective layer 150 may be disposed on an outer surface of the PCB. This may be a result of forming the first protective layer 150 on the side surface of each unit substrate after singulating the substrate of the panel unit or strip unit in the manufacturing operation of the PCB according to an example. The first protective layer 150 may be formed on the side surface of the PCB by a method, such as liquid coating or spraying, and may also be formed by dipping one side of the PCB into a liquid material. The first protective layer 150 may extend to at least a portion of the side surface of the glass layer 110, the upper surface of the glass layer 110, and the side surface of the first insulating layer 111 to be integrally formed. Here, the first protective layer 150 is not limited to covering at least a portion of the upper surface of the glass layer 110, and the first protective layer 150 may also cover at least a portion of the lower surface of the glass layer 110. In addition, the first protective layer 150 may cover at least a portion of the side surface of the solder resist layer 140. This may be a result of singulating the substrate of the strip unit after forming the solder resist layer 140. The present disclosure is not necessarily limited thereto, and in a case in which the solder resist layer 140 is formed after the first protective layer is formed after the singulation operation, the solder resist layer 140 may be formed on the first protective layer 150.

Here, the outer side of the first protective layer 150 may be substantially flat, and in this case, the outer side of the PCB according to an example may be substantially flat. Without being limited thereto, and the outer side of the first protective layer 150 may be formed conformally along the shape of the side surface of the first insulating layer 111 and the side surface of the glass layer 110.

In addition, the first protective layer 150 of the PCB according to the example may have a greater coefficient of thermal expansion than the first insulating layer 111, and the first protective layer 150 may have a greater coefficient of thermal expansion than the glass layer 110. Since the first protective layer 150 may have a greater coefficient of thermal expansion than the first insulating layer 111, the PCB according to the example may prevent cracks occurring in the glass layer 110 from growing. In addition, during the operation of singulation into the unit substrate, the first protective layer 150 may partially penetrate into the cracks occurring in the outer surface of the glass layer 110 to reduce the cracks, and since residual compressive stress may be created in the glass layer 110, the function of preventing cracks may be performed doubly. In addition, since the outermost side of the PCB may be formed of the first protective layer 150, it is possible to prevent external impact from being directly applied to the glass layer 110, prevent the glass layer 110 from being broken by external impact, and protect the first insulating layer 111 and the solder resist layer 140 from external impact applied to the side surface of the first insulating layer 111 or impact applied to the side surface of the solder resist layer 140.

The first protective layer 150 may include an insulating material and may include an organic insulating material. The first protective layer 150 may use an underfill material and may use a known underfill material. In addition, as the organic insulating material, a material used as a solder resist may also be used depending on the case. The organic insulating material may include a thermosetting resin and an inorganic filler dispersed in the thermosetting resin, but may not include glass fiber. The insulating resin may be a photosensitive insulating resin, but may also be a resin, such as epoxy, and the filler may be an inorganic filler and/or an organic filler, but is not limited thereto, and other polymer materials may be used as needed. The first protective layer 150 be formed of a material which has a high coefficient of thermal expansion and is formed on the side surface of the PCB to protect the PCB from damage without limitation in type but is not limited thereto. That is, as long as the first protective layer 150 includes an insulating material having a coefficient of thermal expansion greater than that of each of the first insulating layer 111 and the glass layer 110, it may be used without limitation.

Here, the first protective layer 150 may include a material substantially different from the first insulating layer 111. The first insulating layer 111 is an insulating material used for interlayer insulation insulating between the first interconnection layers 121 of the PCB, while the first protective layer 150 is not intended for interlayer insulation but is intended to protect the glass layer 110 and the first insulating layer 111, so the first protective layer 150 may include a material substantially different from the first insulating layer 111.

The first protective layer 150 may be formed by a method of coating an insulating material in a liquid state and then curing the same, but it is not necessarily limited thereto. Here, a method of forming the first protective layer 150 on the outside of the PCB, such as spraying or dipping, may be used without limitation and is not necessarily limited to being formed by coating.

The first protective layer 150 may include one or more protective layers. In FIG. 1, the first protective layer 150 is illustrated as being one layer, but is not limited thereto, and the first protective layer 150 may include a plurality of first protective layers 150. When the first protective layer 150 includes a plurality of first protective layers 150, each of the plurality of first protective layers 150 may include substantially the same insulating material, but is not necessarily limited thereto, and may include different insulating materials. When the first protective layer 150 includes a plurality of protective layers, a plurality of first protective layers 150 may be formed through an operation in which another first protective layer 150 is formed after one first protective layer 150 is formed. In this case, the boundary between each first protective layer 150 may be confirmed, but it is not necessarily limited thereto, and the boundary between the plurality of first protective layers 150 may not be apparent. Here, the boundary between the plurality of first protective layers 150 may be ascertained by observing a cut section of the PCB with a scanning microscope.

In FIG. 1, the configuration of the PCB is depicted as being symmetrical based on the glass layer 110, but this is an expression for convenience and is not necessarily limited thereto. For example, the number of first insulating layers 111 located above the glass layer 110 may be different from the number of first insulating layers 111 located below the glass layer 110, and the first interconnection layers 121 disposed on the upper and lower surfaces of the glass layer 110 may be different from each other, and the first interconnection layer 121 may not be disposed on one of the upper or lower surfaces of the glass layer 110, thereby having an asymmetrical structure.

The PCB according to the example is not limited to the configuration illustrated in FIG. 1 and may further include general components of PCB, and some of the components may be omitted. In other words, the PCB may further include a component that may be utilized by a person skilled in the art.

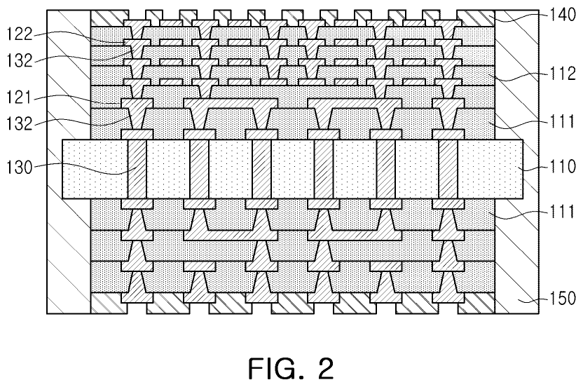

FIG. 2 is a cross-sectional view schematically illustrating another example of a PCB.

According to another example, the PCB may further include a second insulating layer 112 disposed on the first insulating layer 111 and a second interconnection layer 122 disposed on the second insulating layer 112, and an average pitch of the second interconnection layer 122 may be smaller than an average pitch of the first interconnection layer 121.

The PCB according to another example may have an asymmetrical structure in which insulating layer structure stacked on the upper side of the glass layer 110 and the number of insulating layers stacked on the lower side are not symmetrical. Even if the upper and lower sides of the glass layer 110 are not symmetrical to each other, stiffness may be secured through the glass layer 110, and thus, the PCB may be protected from bending. Without being limited thereto, even if the insulating materials of the first insulating layer 111 and the second insulating layer 112 have different compositions, the PCB may be protected from warpage.

The second insulating layer 112 may include one or more insulating layers and may include an organic insulating material. The organic insulating material may include a thermosetting resin, such as an epoxy resin, a thermoplastic resin, such as a polyimide, or a material including an inorganic filler, an organic filler, and/or glass fiber (glass cloth, glass fabric, etc.) together with a resin. For example, the insulating material may be a non-photosensitive insulating material, such as ABF or PPG, but is not limited thereto, and other polymer materials may also be used. In addition, the insulating material may be a photosensitive insulating material, such as PID. In addition, the insulating material may include an adhesive sheet, such as BS. The second insulating layer 112 may be disposed on the first insulating layer 111, but is not necessarily limited thereto and may be directly stacked on the glass layer 110 to be in contact with the glass layer 110.

The first insulating layer 111 and the second insulating layer 112 may include different insulating materials. The fact that the first insulating layer 111 and the second insulating layer 112 may include different insulating materials means that they include different types of insulating materials in the aforementioned insulating material group, and even if they correspond to the same type of insulating materials, the type or composition ratio of the composition of the insulating material of the first insulating layer 111 may be different from the type or composition ratio of the composition of the insulating material of the second insulating layer 112. For example, the first insulating layer 111 and the second insulating layer 112 may each include the ABF, but the composition included in the first insulating layer 111 and the composition included in the second insulating layer 112 may be different. That is, the first insulating layer 111 and the second insulating layer 112 may each include fillers, but the fillers may be different, so that the first insulating layer 111 and the second insulating layer 112 may include different insulating materials. Alternatively, the filler included in the second insulating layer 112 may have a finer structure than the filler included in the first insulating layer 111. In this case, the filler may be an inorganic filler, but is not necessarily limited thereto. The fact that the filler included in the second insulating layer 112 is finer than the filler included in the first insulating layer 111 may refer to that the size, such as a diameter or volume, of the filler included in the second insulating layer 112 is smaller than the size, such as a diameter or volume, of the filler included in the first insulating layer 111. Since the second insulating layer 112 may include a filler finer than the inorganic filler of the first insulating layer 111, the second insulating layer 112 may be more advantageous for fine pattern processing than the first insulating layer 111, and thus the second interconnection layer 122 disposed on the second insulating layer 112 may include an interconnection finer than the first interconnection layer 121.

The fact that the fillers included in the first insulating layer 111 and the second insulating layer 112 are different from each other may be confirmed by analyzing a vertical cross-section of the PCB. Each filler may be compared using a scanning microscope or an optical microscope based on the polished or cut cross-section of the PCB, and if necessary, a vertical cross-section may be dyed to more easily identify the filler. The diameter of the filler may be measured using a scanning microscope or an optical microscope based on the polished or cut cross-section of the PCB as described above, and an average value may be compared as an average value of the values measured at any five points.

The second interconnection layer 122 may include one or more interconnection layers and may include a metal. The metal may include copper (Cu), aluminum (Al), silver (Ag), tin (Sn), gold (Au), nickel (Ni), lead (Pb), titanium (Ti), and/or alloys thereof. Preferably, the second interconnection layer 122 may include copper (Cu), but is not limited thereto. The second interconnection layer 122 may perform various functions depending on the design. For example, the second interconnection layer 122 may include a signal pattern, a power pattern, a ground pattern, etc. Each of these patterns may have various shapes, such as a line, a plane, and a pad. The second interconnection layer 122 may include an electroless plating layer (or chemical copper) and an electrolytic plating layer (or electrolytic copper). Alternatively, the second interconnection layer 122 may include a metal foil (or copper foil) and an electrolytic plating layer (or electrolytic copper). Alternatively, the second interconnection layer 122 may include a metal foil (or copper foil), an electroless plating layer (or chemical copper), and an electrolytic plating layer (or electrolytic copper). The second interconnection layer 122 may include a sputtering layer, instead of the electroless plating layer (or chemical copper), and may include both, and if necessary. The second interconnection layer 122 may be disposed on the second insulating layer 112, but is not limited thereto, and may be disposed directly on the upper surface and/or lower surface of the glass layer 110.

The second interconnection layer 122 may be formed by, but is not limited to, one of SAP, MSAP, TT, or a subtractive method, but is not limited thereto, and any method that may form a circuit on a PCB may be used without limitation. In addition, the second interconnection layer 122 may be formed by different methods depending on the purpose and design, etc.

An average pitch of the second interconnection layer 122 may be smaller than an average pitch of the first interconnection layer 121. That is, an average distance between interconnection patterns of the second interconnection layer 122 may be closer than an average distance between interconnection patterns of the first interconnection layer 121, and an interconnection density of the second interconnection layer 122 may be greater than an interconnection density of the first interconnection layer 121.

The average pitch of the second interconnection layer 122 may be measured by imaging a cut section of the PCB with a scanning microscope, and the average pitch may be an average value of the pitches between the interconnections measured at five arbitrary points. An average interlayer insulation distance may also be measured by imaging a cut section of the PCB with a scanning microscope, and the average interlayer insulation distance may be an average value of insulation distances between the interconnection layers adjacent to each other vertically measured at five arbitrary points.

That is, the interconnection included in the second interconnection layer 122 may be a high-density fine interconnection with a smaller line/space (L/S) than the interconnection included in the first interconnection layer 121. As a non-limiting example, the interconnection included in the second interconnection layer 122 may have a line/space of approximately 2/2 μm, but is not limited thereto. Since the interconnection density of the second interconnection layer 122 is high, it may be effective when interconnecting electronic components, such as semiconductor chips. That is, the second interconnection layer 122 may be used as a redistribution layer for semiconductor chips, etc. by mounting semiconductor chips, etc.

In general, PCBs including interconnection layers with fine interconnection often experience warping due to asymmetry of the substrate. However, since the PCB according to another example includes the glass layer 110 with excellent rigidity, even if the interconnection layer with fine interconnection is implemented only on one side of the substrate, warping due to asymmetry may be prevented.

The PCB according to another example may further include a second via layer 132 penetrating through at least a portion of the second insulating layer 112 to connect the second interconnection layers 122 to each other. The second via layer 132 may include a metal. The metal may include copper (Cu), aluminum (Al), silver (Ag), tin (Sn), gold (Au), nickel (Ni), lead (Pb), titanium (Ti), and/or alloys thereof. Preferably, the second via layer 132 may include copper (Cu), but is not limited thereto. The second via layer 132 may include a filled via filling each via hole, but may also include a conformal via disposed along a wall surface of the via hole. The second via layer 132 may perform various functions depending on the design. For example, the second via layer 132 may include a ground via, a power via, a signal vias, etc. The second via layer 132 may include an electroless plating layer (or chemical copper) and an electrolytic plating layer (or electrolytic copper), similar to the second interconnection layer 122. Alternatively, the second via layer 132 may include a metal foil (or copper foil) and an electrolytic plating layer (or electrolytic copper). The second via layer 132 may include a sputtering layer, instead of the electroless plating layer (or chemical copper), and may include both if necessary. A width of the second insulating layer 112 may be narrower than a width of the glass layer 110, and the width of the second insulating layer 112 may be substantially the same as the width of the first insulating layer 111. This may be a result of performing an operation of removing a portion of the second insulating layer 112 in the operation of removing a portion of the first insulating layer 111 in the method for manufacturing a PCB according to another example, and then performing an operation of cutting the glass layer 110. Since the first insulating layer 111 and the second insulating layer 112 each include an organic insulating material, the operation of removing a portion of the second insulating layer 112 may be performed in the operation of removing a portion of the first insulating layer 111.

The first protective layer 150 may cover at least a portion of the side surface of the second insulating layer 112. This may be a result of forming the first protective layer 150 after cutting the glass layer 110 and singulating it into a unit-based substrate, and the first protective layer 150 may cover at least a portion of the side surface of the glass layer 110, a portion of the upper and lower surfaces of the glass layer 110, at least a portion of the side surface of the first insulating layer 111 and may extend to cover at least a portion of the side surface of the second insulating layer 112.

In the PCB according to another example, the solder resist layer 140 may be disposed on the second insulating layer 112. The first protective layer 150 may cover at least a portion of the side surface of the solder resist layer 140 in the same manner as the PCB according to the example.

In the PCB according to another example of FIG. 2, descriptions other than those regarding the second insulating layer 112 and the second interconnection layer 122 may be applied in the same manner as the description of the PCB according to the example, and therefore, redundant descriptions are omitted.

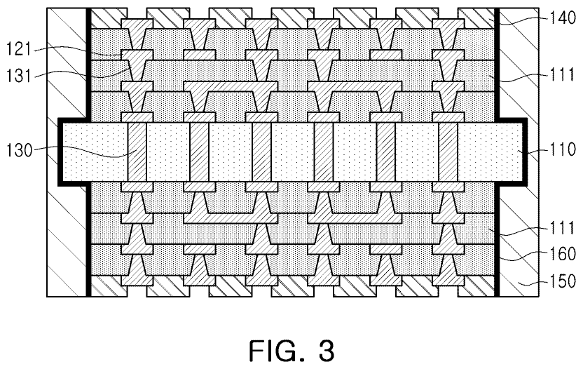

FIG. 3 is a cross-sectional view schematically illustrating another example of the PCB.

The PCB according to another example may further include a second protective layer 160 disposed between the glass layer 110 and the first protective layer 150. The second protective layer 160 may contact at least a portion of the side surface of the glass layer 110, a portion of the upper and lower surfaces of the glass layer 110, and at least a portion of the side surface of the first insulating layer 111. That is, the second protective layer 160 may be disposed between the glass layer 110 and the first protective layer and may extend to be disposed between the side surface of the first insulating layer 111 and the first protective layer 150. The coefficient of thermal expansion of the second protective layer 160 may be greater than the coefficient of thermal expansion of the first insulating layer 111 and may be greater than the coefficient of thermal expansion of the glass layer 110.

The second protective layer 160 may include an insulating material and may include an organic insulating material. The second protective layer 160 may function as a unit for improving adhesion between the first protective layer 150 and the stack of the PCB. As a non-limiting example, the second protective layer 160 may include a resin, such as epoxy, and the filler may be an inorganic filler and/or an organic filler, but is not limited thereto, and other polymer materials may be used as needed. Alternatively, the second protective layer 160 may include a bonding sheet, a coupling agent, or the like. That is, a material securing adhesion with the glass layer 110 or securing adhesion with the side surface of the first insulating layer 111 that has been stacked and cured may be used without limitation.

The insulating material of the second protective layer 160 is not limited thereto and the second protective layer 160 may include one material from an insulating material group of the first protective layer 150. That is, the second protective layer 160 may use an underfill material and may use a known underfill material. In addition, as described above in the description of the PCB according to an example, the material used as a solder resist in some cases may also be used as the organic insulating material and repeated contents will be omitted.

Since the second protective layer 160 may be formed in an operation different from the operation of forming the first protective layer 150, the boundary between the first protective layer 150 and the second protective layer 160 may be observed by scanning microscopy in the cross-section of the PCB. However, without being limited thereto, if the first protective layer 150 is formed immediately after the second protective layer 160 is formed, the boundary between the first protective layer 150 and the second protective layer 160 may not be apparent. The method of forming the second protective layer 160 may be performed using the same method as the method of forming the first protective layer 150, but the present disclosure is not necessarily limited thereto, and the second protective layer 160 may be formed in various manners depending on the material of the second protective layer 160.

Here, the second protective layer 160 may include one or more protective layers. In FIG. 3, the second protective layer 160 is illustrated as being a single layer, but without being limited thereto, the second protective layer 160 may include a plurality of second protective layers 160. When the second protective layer 160 includes a plurality of second protective layers 160, each of the plurality of second protective layers 160 may include substantially the same insulating material, but is not necessarily limited thereto, and may include different insulating materials. When the second protective layer 160 includes a plurality of protective layers, a plurality of second protective layers 160 may be formed through an operation of forming another second protective layer 160 after one second protective layer 160 is formed. In this case, the boundary between each of the second protective layers 160 may be confirmed, but is not necessarily limited thereto, and the boundary between the plurality of second protective layers 160 may not be apparent. Here, the boundary between the plurality of second protective layers 160 may be confirmed by observing a cut cross-section of the PCB with a scanning microscope.

The description other than the presence or absence of the second protective layer 160 in the PCB according to another example of FIG. 3 may be applied in the same manner as the description of the PCB according to an example and the PCB according to another example, and thus, redundant descriptions are omitted.

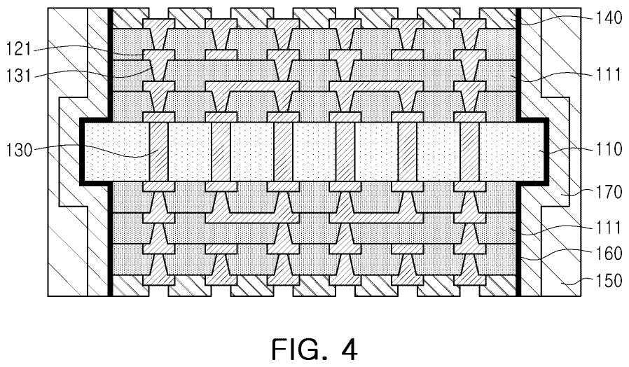

FIG. 4 is a cross-sectional view schematically illustrating another example of a PCB.

The PCB according to another example may further include a third protective layer 170 disposed between the second protective layer 160 and the first protective layer 150. The third protective layer 170 may be disposed on the second protective layer 160 and may be conformally disposed along the boundary of the second protective layer 160. The third protective layer 170 may have a greater coefficient of thermal expansion than the first insulating layer 111, and the third protective layer 170 may have a greater coefficient of thermal expansion than the glass layer 110. The third protective layer 170 may prevent cracks occurring in the glass layer 110 from growing, similar to the first protective layer 150 and/or the second protective layer 160. In addition, the adhesion between the second protective layer 160 and the first protective layer 150 may be increased.

The third protective layer 170 may include an insulating material, and may include an organic insulating material. The third protective layer 170 may use an underfill material, and may use a known underfill material. In addition, as the organic insulating material, a material used as a solder resist may be used depending on the case. The organic insulating material may include a thermosetting resin and an inorganic filler dispersed in the thermosetting resin, but may not include glass fibers. The insulating resin may be a photosensitive insulating resin, but may also be a resin, such as epoxy, and the filler may be an inorganic filler and/or an organic filler, but is not limited thereto, and other polymer materials may be used as needed. The third protective layer 170 is not limited thereto, and as long as it has a high coefficient of thermal expansion and is formed on the side surface of the PCB to protect the PCB from damage, the type of material may be selected without limitation. That is, as long as the third protective layer 170 includes an insulating material having a coefficient of thermal expansion greater than the coefficient of thermal expansion of each of the first insulating layer 111 and the glass layer 110, it may be used without limitation. The third protective layer 170 may include substantially the same insulating material as the first protective layer 150, but is not necessarily limited thereto, and may include different types of insulating materials. When the third protective layer 170 includes substantially the same insulating material as the first protective layer 150, the third protective layer 170 may have substantially the same coefficient of thermal expansion as the first protective layer 150, but is not necessarily limited thereto, and the third protective layer 170 may have a smaller coefficient of thermal expansion than the first protective layer 150. When the coefficient of thermal expansion of the third protective layer 170 is greater than the coefficient of thermal expansion of the first insulating layer 111 and smaller than the coefficient of thermal expansion of the first protective layer 150, the third protective layer 170 may be provided as an intermediate between the first insulating layer 111 and the first protective layer 150. That is, the third protective layer 170 may play a role in alleviating the degree of thermal expansion of each of the first insulating layer 111 and the first protective layer 150.

The third protective layer 170 may be formed by coating an insulating material in a liquid state and then curing it, but the present disclosure is not necessarily limited thereto. Here, the coating method may be used without limitation as long as there is a method for forming the third protective layer 170 on the outside of the PCB, such as spraying or dipping, and the coating method is not necessarily limited to being formed by coating. According to another example, the PCB is illustrated in which the first protective layer 150 is formed after the third protective layer 170 is formed, but the present disclosure is not necessarily limited thereto, and the boundary between the first protective layer 150 and the third protective layer 170 may not be apparent. In FIG. 4, the third protective layer 170 is formed on the second protective layer 160, but the present disclosure is not necessarily limited thereto, and the second protective layer 160 may be omitted as needed.

In the PCB according to another example of FIG. 4, the description other than the presence or absence of the third protective layer 170 may be applied in the same manner as the description of the PCB according to one example, the PCB according to another example, and the PCB according to another example, and thus, redundant descriptions are omitted.

### Method for Manufacturing PCB

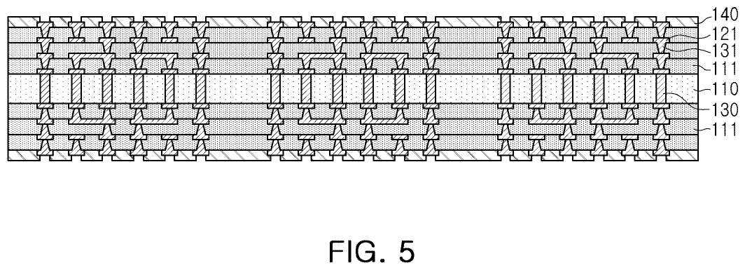

FIGS. 5 to 8 are cross-sectional views schematically illustrating an example of a method for manufacturing a PCB.

The method for manufacturing a PCB according to an example may include an operation of forming a large-area strip substrate into panel units and then singulating each unit substrate. After the singulating operation, the manufacturing method may include an operation of forming the first protective layer 150 on the side surface of the glass layer 110 and the side surface of the first insulating layer 111.

Referring to FIG. 5, the manufacturing method includes an operation of forming the glass layer 110, the first insulating layer 111, the first interconnection layer 121, and the solder resist layer 140. That is, the manufacturing method may include an operation of forming a strip substrate of a panel unit including each unit substrate. Here, in the operation of forming each component, each component may be formed by a method of forming a build-up structure of a known PCB.

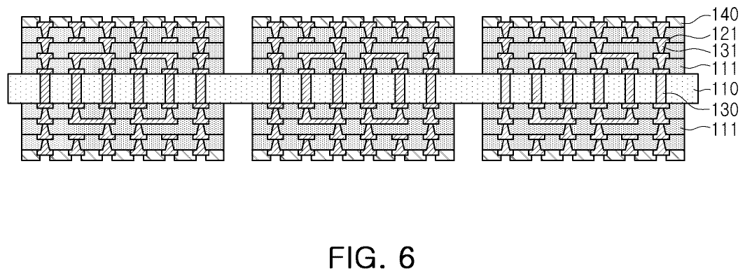

Referring to FIG. 6, the manufacturing method may include an operation of removing a portion of the first insulating layer 111. This is to first remove a portion of the first insulating layer 111 before cutting the glass layer 110 prior to the singulation operation. A portion of the first insulating layer 111 near a cutting line for singulating into the unit substrate may be removed. The operation of removing a portion of the first insulating layer 111 may be performed by a method using a laser, but is not limited thereto. As a non-limiting example, it may be performed by laser ablation. However, the method for removing a portion of the first insulating layer 111 is not limited thereto, and any method that may be used by a technician in the art, such as using a mechanical or chemical method, may be used without limitation. As a result of removing a portion of the first insulating layer 111, a portion of the upper surface and a portion of the lower surface of the glass layer 110 may be exposed to the outside, and a cutting reference may be exposed to the outside.

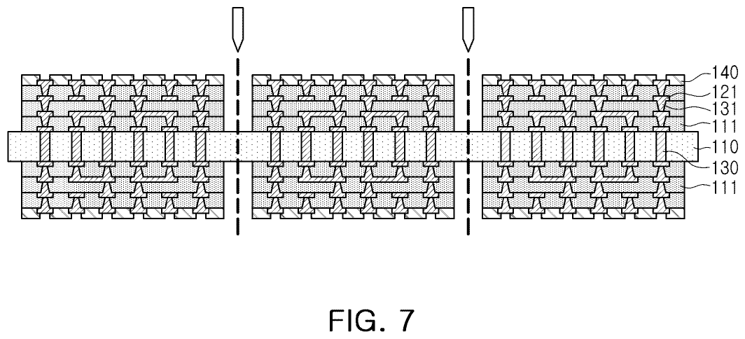

Referring to FIG. 7, the manufacturing method may include an operation of cutting the glass layer 110 and dicing it into a unit substrate. Dicing may be performed along a portion of the upper surface and a portion of the lower surface of the glass layer 110 exposed to the outside and may be performed by a mechanical processing or a chemical method. As a non-limiting example, a sawing process or a laser processing process may be used, a method, such as etching, may be used, and these methods may be used in combination. However, the method of processing and dicing the glass layer 110 is not limited thereto, and any method that may be used by a technician in the art may be used without limitation. Here, since the operation of dicing the glass layer 110 is performed after the operation of removing a portion of the first insulating layer 111, the width of the first insulating layer 111 may be narrower than the width of the glass layer 110, the side surface of the first insulating layer 111 may not be coplanar with the side surface of the glass layer 110, and the side surface of the glass layer 110 may protrude further than the side surface of the first insulating layer 111.

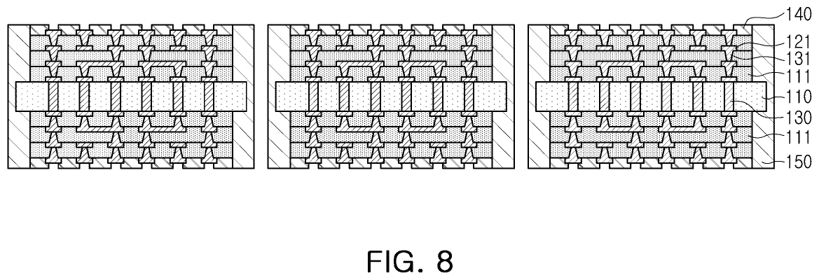

Referring to FIG. 8, the manufacturing method may include an operation of forming the first protective layer 150 on the side surface of the glass layer 110. More specifically, the first protective layer 150 may be formed on at least a portion of the side surface of the glass layer 110, a portion of the upper and lower surfaces of the glass layer 110, and at least a portion of the side surface of the first insulating layer 111. The method of forming the first protective layer 150 may be performed by a method of coating an insulating material in a liquid state and then curing it, but is not necessarily limited thereto. Here, the coating method may be used without limitation as long as there is a method of forming the first protective layer 150 on the outer side of the PCB, such as spraying or dipping. The first protective layer 150 is formed on the side surface of each unit substrate after singulation into the unit substrate, and by forming the first protective layer 150, the side surface of the unit substrate may have a substantially flat surface.

As one of the various effects of the present disclosure, the PCB including a glass layer may be provided.

As another of the various effects of the present disclosure, the PCB capable of complementing the problem of the breakage characteristics of a glass layer may be provided.

As another of the various effects of the present disclosure, the PCB having improved reliability may be provided.

The present disclosure may further include a method of forming a component that may be utilized by a person skilled in the art without being limited to the contents expressed in the drawings. In addition, the method of manufacturing a PCB according to another example and the method of manufacturing a PCB according to another example may also be performed as a method of forming a component that may be utilized by a person skilled in the art, as described above in the contents of the PCB according to another example and the PCB according to another example.

In the present disclosure, the expressions of covering may include not only a case of covering completely but also a case of covering at least partly, and may also include not only a case of covering directly but also a case of covering indirectly. In addition, the expression “fill” may include not only a case of complete filling but also a case of approximate filling and may include a case in which, for example, some airgaps or voids exist.

In the present disclosure, determination may be made to include process errors, position deviations, errors during measurement, and the like that occur during a manufacturing process. For example, substantially being coplanar may include not only presence completely on the same plane, but also presence approximately on the same plane.

In the present disclosure, the same material may refer to not only the same material but also the same type of material. Accordingly, the composition of the materials may be substantially the same, but their specific composition ratios may be slightly different. In the present disclosure, different insulating materials may refer to that they do not correspond to the same insulating material.

In the present disclosure, a cross-section may refer to a cross-sectional shape when an object is cut vertically, a cross-sectional shape when an object is cut vertically, or a cross-sectional shape when an object is viewed from a side view. In addition, “on a plane” may refer to a planar shape when an object is cut horizontally or a planar shape when an object is viewed from a top-view or bottom-view.

In the present disclosure, a lower side, a lower portion, a lower surface, and the like are used to refer to a downward direction based on a cross-section of a drawing for the sake of convenience, and an upper side, an upper portion, an upper surface, and the like are used to mean the opposite direction. However, this defines directions for convenience of description, and the scope of the claims is not particularly limited by the descriptions of the directions, and the concept of top/bottom may change at any time.

In the present disclosure, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” In addition, it may be understood that when an element is referred to with “first” and “second,” the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The expression “an exemplary embodiment or one example” used in the present disclosure does not refer to identical examples and is provided to stress different unique features between each of the examples. However, examples provided in the following description are not excluded from being associated with features of other examples and implemented thereafter. For example, even if matters described in a specific example are not described in a different example thereto, the matters may be understood as being related to the other example, unless otherwise mentioned in descriptions thereof.

What is claimed is:

1. A printed circuit board comprising:
a glass layer;
a first insulating layer disposed on the glass layer; and
a first protective layer covering a portion of an upper surface of the glass layer, at least a portion of a side surface of the glass layer, and at least a portion of a side surface of the first insulating layer.

2. The printed circuit board of claim 1, wherein the first protective layer covers a portion of a lower surface of the glass layer.

3. The printed circuit board of claim 1, further comprising:
a solder resist layer disposed on the first insulating layer,
wherein the first protective layer covers at least a portion of a side surface of the solder resist layer.

4. The printed circuit board of claim 1, wherein the first protective layer includes a material substantially different from the first insulating layer.

5. The printed circuit board of claim 1, further comprising a first interconnection layer disposed on the first insulating layer.

6. The printed circuit board of claim 5, wherein the first insulating layer is disposed on each of upper and lower surfaces of the glass layer, and the first interconnection layer is disposed on each of the upper and lower surfaces of the glass layer.

7. The printed circuit board of claim 5, further comprising:
a second insulating layer disposed on the first insulating layer; and
a second interconnection layer disposed on the second insulating layer.

8. The printed circuit board of claim 7, wherein an average pitch of the second interconnection layer is smaller than an average pitch of the first interconnection layer.

9. The printed circuit board of claim 7, wherein the first protective layer covers at least a portion of the side surface of the second insulating layer.

10. The printed circuit board of claim 9, wherein a width of the second insulating layer is substantially the same as a width of the first insulating layer, and the width of the second insulating layer and the width of the first insulating layer are smaller than a width of the glass layer.

11. The printed circuit board of claim 1, further comprising at least one second protective layer disposed between the glass layer and the first protective layer.

12. The printed circuit board of claim 11, wherein the second protective layer extends between at least a portion of the side surface of the first insulating layer and the first protective layer.

13. The printed circuit board of claim 11, further comprising at least one third protective layer disposed between the second protective layer and the first protective layer.

14. The printed circuit board of claim 1, wherein the first protective layer includes one or more protective layers.

15. The printed circuit board of claim 1, wherein a coefficient of thermal expansion of the first protective layers is greater than a coefficient of thermal expansion of the first insulating layer.

16. The printed circuit board of claim 15, wherein the coefficient of thermal expansion of the first protective layer is greater than a coefficient of thermal expansion of the glass layer.

17. The printed circuit board of claim 15, further comprising:
a second protective layer disposed between the first protective layer and the first insulating layer and disposed between the first protective layer and the glass layer,
wherein a coefficient of thermal expansion of the second protective layer is greater than the coefficient of thermal expansion of the first insulating layer.

18. A printed circuit board comprising:
a glass layer;
a first insulating layer disposed on the glass layer; and
a first interconnection layer disposed on the first insulating layer;
wherein a width of the first insulating layer is smaller than a width of the glass layer.

19. The printed circuit board of claim 18, further comprising a first protective layer covering a portion of an upper surface of the glass layer, at least a portion of a side surface of the glass layer, and at least a portion of a side surface of the first insulating layer.

20. The printed circuit board of claim 19, wherein the first protective layer covers a portion of a lower surface of the glass layer.

21. The printed circuit board of claim 19, further comprising:
a solder resist layer disposed on the first insulating layer,
wherein the first protective layer covers at least a portion of a side surface of the solder resist layer.

22. The printed circuit board of claim 19, wherein the first protective layer includes a material substantially different from the first insulating layer.

23. The printed circuit board of claim 18, wherein the first insulating layer is disposed on each of upper and lower surfaces of the glass layer, and the first interconnection layer is disposed on each of the upper and lower surfaces of the glass layer.

24. The printed circuit board of claim 19, further comprising:
a second insulating layer disposed on the first insulating layer; and
a second interconnection layer disposed on the second insulating layer.
